(19) United States
(12) Patent Application Publication
(10) Pub. No.: US 2024/0170313 A1
(43) Pub. Date: May 23, 2024

(54) SECURE ONE-TIME WAFER IDENTIFICATION IN SPLIT MANUFACTURING

(71) Applicant: INTERNATIONAL BUSINESS MACHINES CORPORATION, Armonk, NY (US)

(72) Inventors: Carl Radens, LaGrangeville, NY (US); Kangguo Cheng, Schenectady, NY (US); Juntao Li, Cohoes, NY (US); Ruilong Xie, Niskayuna, NY (US)

(21) Appl. No.: 17/991,997

(22) Filed: Nov. 22, 2022

(51) Int. Cl. H01L 21/67; G06T 7/00

(52) U.S. Cl. CPC H01L 21/67282; G06T 7/0004; G06T 2207/30204

(57) ABSTRACT

A method of wafer verification for split manufacturing is provided. The method includes capturing images of one or more different wafer features during manufacturing using a fiducial marker. The method further includes comparing the images from one stage to a next stage for at least two stages of manufacturing to verify a wafer identification based on a matching of the one of more different wafer features from the one stage to the next stage.

### BACKGROUND

The present invention generally relates to semiconductor manufacturing, and more particularly to secure one-time identification in split manufacturing.

Preventing trojan hardware has become increasingly important in ensuring chip authenticity and preventing information leaking.

Split chip manufacturing in multiple foundries is an effective way to reduce trojan hardware. In split manufacturing, chips are manufactured by multiple foundries (sites) so each foundry can only have partial information about the chips, significantly increasing the difficulty for a compromised foundry to implant trojan hardware on wafers.

Split manufacturing, however, creates a new security issue. During wafer transfer from one foundry to the next foundry, an adversary can conceivable replace the original wafers in the previous foundries with wafers implanted with compromised wafers. Therefore, there is a need to ensure wafer authenticity during split manufacturing.

### SUMMARY

According to aspects of the present invention, a method of wafer verification for split manufacturing is provided. The method includes capturing images of one or more different wafer features during manufacturing using a fiducial marker. The method further includes comparing the images from one stage to a next stage for at least two stages of manufacturing to verify a wafer identification based on a matching of the one of more different wafer features from the one stage to the next stage.

According to other aspects of the present invention, a wafer verification system for split manufacturing is provided. The system includes a wafer imaging system, disposed at each of a plurality of foundries performing the split manufacturing of a wafer, for capturing images of one or more different wafer features during manufacturing using a fiducial marker. The system further includes a hardware processor, disposed at each of the plurality of foundries except a first foundry, for comparing the images from one stage to a next stage for at least two stages of manufacturing to verify a wafer identification based on a matching of the one of more different wafer features from the one stage to the next stage.

According to yet other aspects of the present invention, a wafer verification system for split manufacturing is provided. The system includes a wafer imaging system, disposed at each of a plurality of foundries performing the split manufacturing of a wafer, for capturing images of one or more different wafer features during manufacturing using a fiducial marker. The system further includes a hardware processor, disposed at each of the plurality of foundries except a first foundry, for comparing the images from one stage to a next stage for at least two stages of manufacturing to verify a wafer identification based on a matching of the one of more different wafer features from the one stage to the next stage. The one or more different wafer features are selected from the group consisting of a grain distribution, an electrical test probe mark distribution, wafer bevel edge characteristics, and a grain crystallographic structure.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram of a computing environment, in accordance with an embodiment of the present invention;

FIG. 2 is a block diagram showing an exemplary environment to which the present invention can be applied, in accordance with an embodiment of the present invention;

FIG. 3 is a flow diagram showing an exemplary method, in accordance with an embodiment of the present invention;

FIG. 4 is a flow diagram further showing block 324 of the method of FIG. 3, in accordance with an embodiment of the present invention;

FIG. 5 is a block diagram showing a top-down schematic of metal grains in a metal line or via surrounded by a dielectric, in accordance with an embodiment of the present invention;

FIG. 6 is a block diagram showing a top-down schematic of electrical test probe marks, in accordance with an embodiment of the present invention;

FIG. 7 is a block diagram showing a top-down schematic of a wafer bevel edge structure, in accordance with an embodiment of the present invention; and

FIG. 8 is a block diagram showing a top-down schematic of a grain crystallographic morphology/structure, in accordance with an embodiment of the present invention.

### DETAILED DESCRIPTION

Embodiments of the present invention are directed to secure one-time identification in split manufacturing.

Embodiments of the present invention provide a structure and method to ensure wafer authenticity during wafer transfer by taking advantage of inline metrology during chip manufacturing.

Embodiments of the present invention are specifically directed to split manufacturing and are able to overcome the above mentioned deficiencies regarding the use of trojan hardware.

Embodiments of the present invention include a plurality of different approaches to ensure wafer authenticity during wafer transfer. It is to be appreciated that, in particular, four different approaches are provided for illustrative purposes.

In consideration of the fact that electron microscope images are taken regularly for wafer inspection and/or measuring critical dimensions, a first embodiment of the present invention can use the distribution of grain characteristics of a wafer in combination with a fiducial marker to ensure wafer authenticity during wafer transfer for split manufacturing. The fiducial marker is used to provide location reference. The fiducial mark cab be a notch, or flat, or patterned structure on a wafer surface, preferably away from a flat/edge. In an embodiment, the patterned structure fiducial mark can be part of a circuit or kerf.

In a second embodiment of the present invention, electrical test probe marks on the wafer can be used. For example, electrical test probe marks made during or to verify the back-end-of-line (BEOL) process can be used to ensure wafer authenticity during wafer transfer for split manufacturing.

In a third embodiment, a wafer bevel edge structure can be used. The wafer bevel edge structure typically varies from wafer to wafer and can be exploited by embodiments of the present invention to ensure wafer authenticity during wafer transfer for split manufacturing.

In a fourth embodiment, a grain crystallographic morphology can be used. The grain crystallographic morphology typically varies from wafer to wafer and can be exploited by embodiments of the present invention to ensure wafer authenticity during wafer transfer for split manufacturing.

While four wafer features have been described as the basis for use to ensure wafer authenticity during wafer transfer, one of ordinary skill in the art will contemplate these and other wafer features to which the present invention can be applied, given the teachings of the present invention provided herein.

It is to be appreciated that conventional wafer identification techniques which contain letters and numbers on a wafer back can be easily forged. In contrast, the wafer identification in this invention is extremely difficult if not impossible to clone.

It is to be further appreciated that unlike conventional Physical Unclonable Functions (PUFs) which are permanent, the wafer identification methods of the present invention are temporary. Once the subsequent layers are added onto the wafer in a subsequent foundry, the wafer identification information is no longer retrievable. In other words, the identification approach in this invention is analogous to a one-time passcode.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

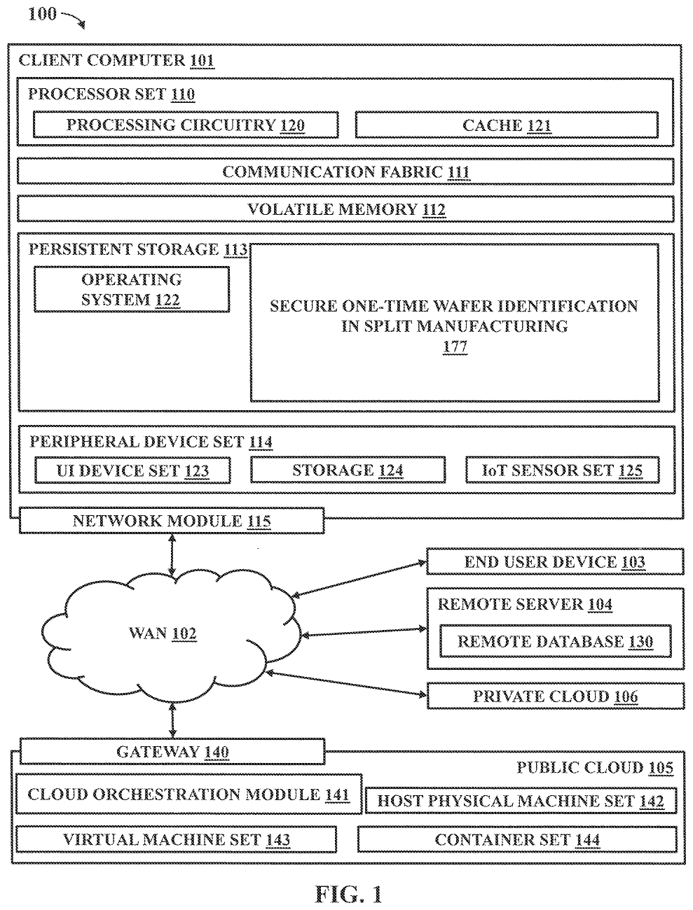

FIG. 1 is a block diagram of a computing environment 100, in accordance with an embodiment of the present invention.

Computing environment 100 contains an example of an environment for the execution of at least some of the computer code involved in performing the inventive methods, such as secure one-time wafer identification in split manufacturing 177. In addition to block 177, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 177, as identified above), peripheral device set 114 (including user interface (UI), device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 177 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 177 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

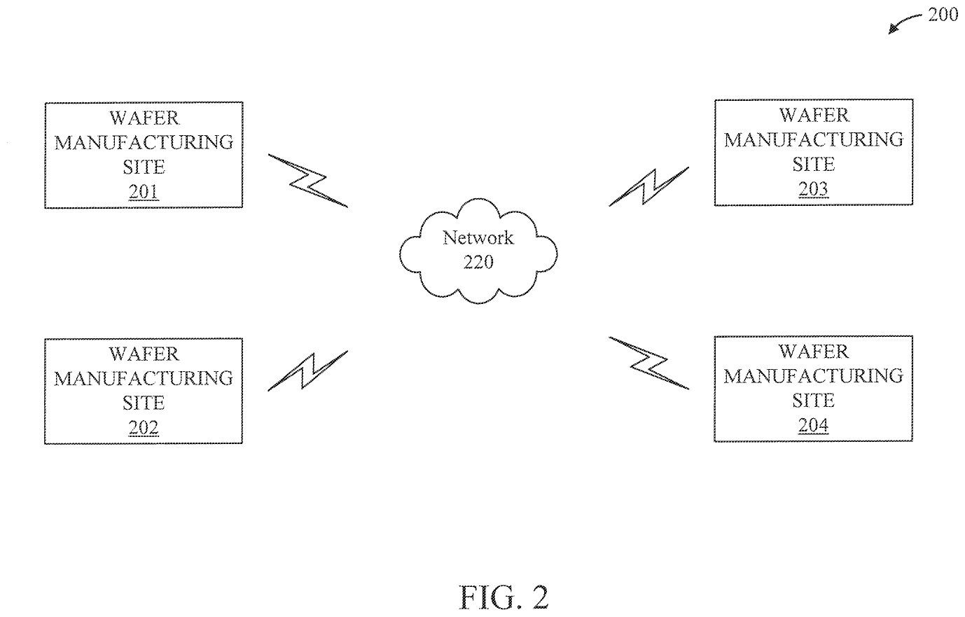

Computing environment 100 can further include and/or otherwise be connected to a wafer manufacturing system (e.g., a foundry). Computing environment 100 can be duplicated numerous times, once for each foundry to which the present principles are to be applied in a split manufacturing (multiple foundry) scenario. FIG. 2 shows an environment to which the present invention can be applied, where each of the manufacturing sites 201-204 in FIG. 2 includes and/or otherwise connects to a computing environment 100 that, in turn, includes and/or is otherwise connected to a respective foundry. In an embodiment, each foundry receives images from the previous foundry and compares them to its own taken images to verify wafer authenticity. In another embodiment, a cloud portion of computing environment 100 can be used by embodiments of the present invention to compare images sent thereto for purposes of wafer authenticity, thus enhancing security by performing the verification at least partly off-site. Communication between the computing environments 100 and the foundries are secure, preferably encrypted.

FIG. 2 is a block diagram showing an exemplary environment 200 to which the present invention can be applied, in accordance with an embodiment of the present invention.

The environment 200 includes a plurality of wafer manufacturing sites 201-204. Each of the wafer manufacturing sites 201-204 includes a respective computing environment 100 that, in turn, includes and/or is otherwise connected to and controls a wafer manufacturing system for performing one more steps of a wafer manufacturing process. Collectively, the manufacturing sites 201-204 process the wafer. In an embodiment, the foundries communicate wirelessly through one or more wireless networks 220, as shown. In another embodiment, the foundries communicate using wired technology. In yet another embodiment, a mix of wired and wireless technologies can be used.

At each site 201-204, one or more different steps are performed to manufacture a wafer according to a specification. For example, a first site may initially process the wafer. Subsequent sites 202 and 203 may add metallization (BEOL, FEOL) and/or other layers to the wafer in order to provide a finished wafer at a last site 204. Each of the sites 201-204 is a fully operational semiconductor manufacturing facility capable of handling at least a portion of a wafer fabrication task. Each of the sites 201-204 includes a fully functioning server with site-to-site communication capabilities and also includes the machinery necessary for wafer manufacturing and inspection including, for example, an electron microscope. These and other features of the sites 201-204 are readily determined by one of ordinary skill in the art given the teachings of the present invention provided herein.

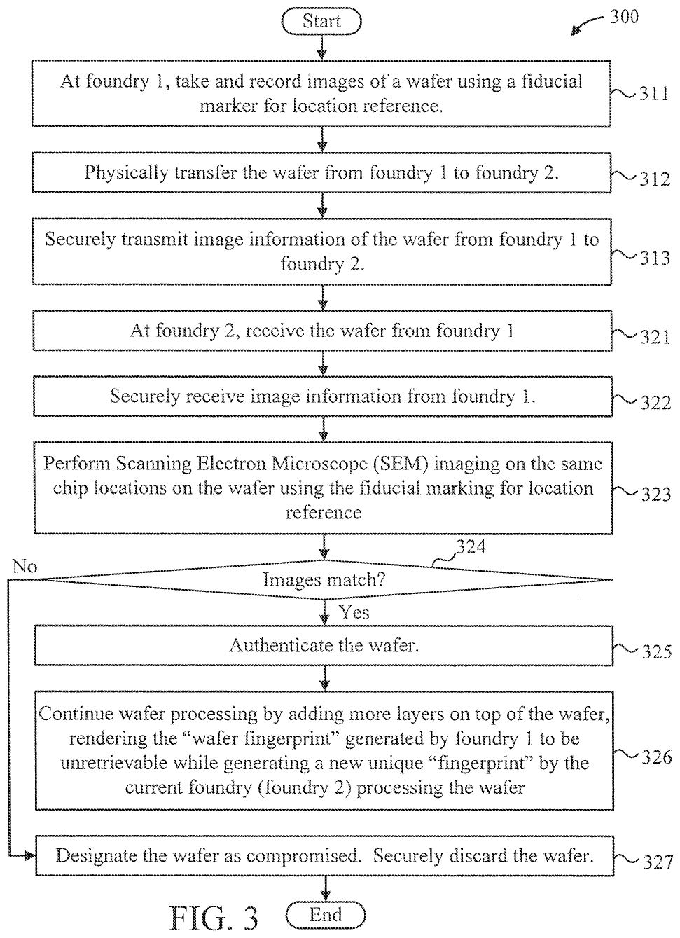

FIG. 3 is a flow diagram showing an exemplary method 300, in accordance with an embodiment of the present invention. Blocks 311-313 are performed by a first foundry (foundry 1), while blocks 321-327 are performed by a second foundry (foundry 2).

At block 311, at foundry 1, take and record images of a wafer using a fiducial marker for location reference.

At block 312, physically transfer the wafer from foundry 1 to foundry 2.

At block 313, securely transmit (e.g., electronically) image information of the wafer from foundry 1 to foundry 2.

At block 321, at foundry 2, receive the wafer from foundry 1.

At block 322, securely receive (e.g., electronically) image information from foundry 1.

At block 323, perform Scanning Electron Microscope (SEM) imaging on the same chip locations on the wafer using the fiducial marking for location reference.

At block 324, compare the images from foundry 2 with the images from foundry 1 and determine if they match. If so, then proceed to block 325. Otherwise, proceed to block 326.

At block 325, authenticate the wafer.

At block 326, designate the wafer as compromised. In an embodiment, block 326 can include securely discarding the compromised wafer. This can involve placing the comprised wafer in a electronically shielded enclosure and/or discarding the wafer immediately off-premises.

At block 327, continue wafer processing by adding more layers on top of the wafer, rendering the “wafer fingerprint” generated by foundry 1 to be unretrievable while generating a new unique “fingerprint” by the current foundry (foundry 2) processing the wafer.

While method 300 is described with respect to a first foundry (foundry 1) and a second foundry (foundry 2), in other embodiments, any number of foundries can be involved, where each of the involved foundries generates a unique “fingerprint” that can be exploited by a next foundry in order to verify an authenticity of the wafer. In this way, trojan hardware implantation can be avoided during the wafer manufacturing process.

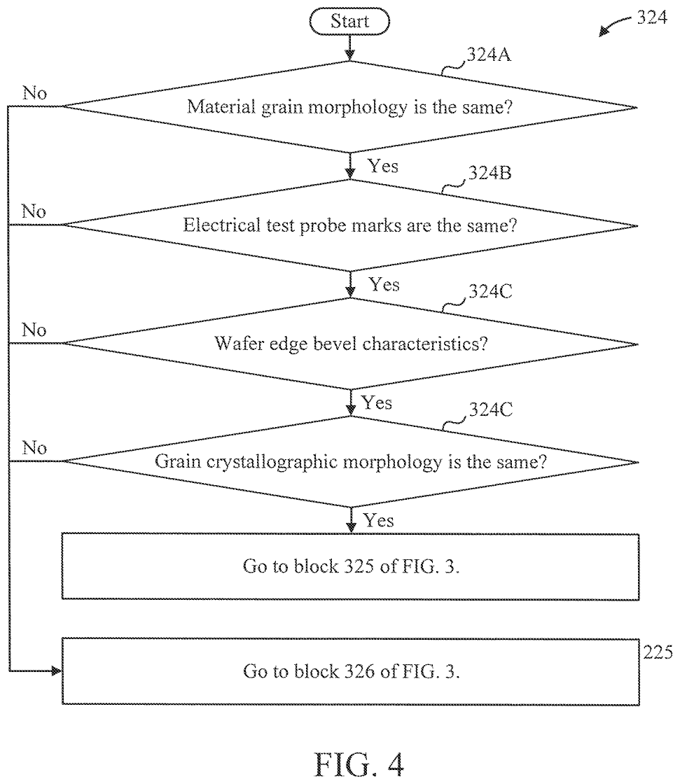

FIG. 4 is a flow diagram further showing block 324 of method 300 of FIG. 3, in accordance with an embodiment of the present invention. It is to be appreciated that the order of the following steps may differ based on actual implementation.

At block 324A, determine, using the fiducial marker, if the material grain morphology is the same between the images from foundry 1 and foundry 2. If so, then proceed to block 324B. Otherwise, proceed to block 326.

At block 324B, determine, using the fiducial marker, if the electrical test probe marks are the same between the images from foundry 1 and foundry 2. If so, then proceed to block 324C. Otherwise, proceed to block 326.

At block 324C, determine, using the fiducial marker, if the wafer edge bevel characteristics are the same between the images from foundry 1 and foundry 2. If so, then proceed to block 324D. Otherwise, proceed to block 326.

At block 324D, determine, using the fiducial marker, if the grain crystallographic morphology is the same between the images from foundry 1 and foundry 2. If so, then proceed to block 325. Otherwise, proceed to block 326.

It is noted that images are regularly taken by an electron microscope for wafer inspection and/or measuring Critical Dimensions (CDs). These images can be used to perform blocks 324A through 324D.

A further description will now be given regarding block 324A of method 300 of FIG. 3, in accordance with an embodiment of the present invention.

The last process in the first foundry can be metallization (e.g., metallization with Copper, Tungsten, Ruthenium, Aluminum, and so forth). SEM images include metal grain shapes and sizes. The shapes and sizes of metal grains are random and vary from chip to chip and from wafer to wafer. It is difficult if not impossible to clone a wafer with the identical grain distribution of another wafer. Hence, the distribution of grain characteristics (e.g., grain shapes, grain sizes, or both) can be used as a unique identification of a wafer. A fiducial marker is used in combination with the images to provide reference location and reproducibility. In an embodiment, the images taken from multiple chips of a wafer can be combined to further enhance the uniqueness of wafer identification.

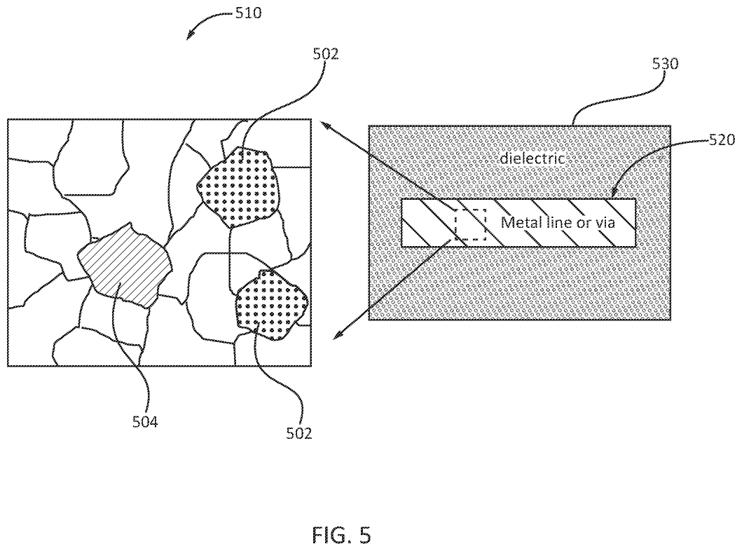

FIG. 5 is a block diagram showing a top-down schematic of metal grains 510 in a metal line or via 520 surrounded by a dielectric 530, in accordance with an embodiment of the present invention. As can be seen, the sizes and shapes and locations of the grains are different from grain to grain, thus providing a unique fingerprint of the wafer upon which the metal line or via 520 is placed. Grains of one material 502 are shown with a grain of another material 504.

A further description will now be given regarding block 324B of method 300 of FIG. 3, in accordance with an embodiment of the present invention.

A set of inline electrical test probe marks can be used as wafer identifying indicia in order verify the authenticity of a wafer. SEM images include electrical test probe marks. The locations of electrical test probe marks can be random and vary from chip to chip and from wafer to wafer. It thus can be difficult if not impossible to clone a wafer with the electrical test probe mark distribution of another wafer. Hence, the distribution of electrical test probe marks can be used as a unique identification of a wafer. A fiducial marker is used in combination with the images to provide reference location and reproducibility. In an embodiment, the images taken from multiple chips of a wafer can be combined to further enhance the uniqueness of wafer identification.

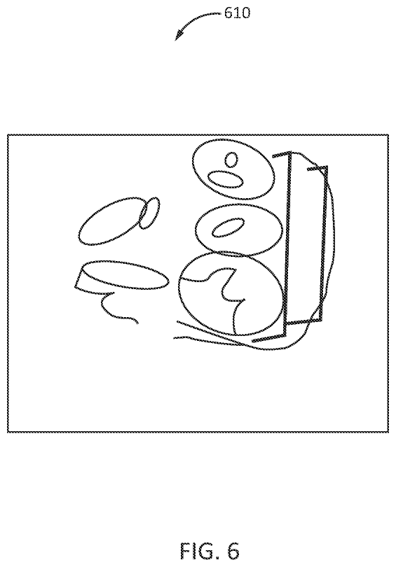

FIG. 6 is a block diagram showing a top-down schematic of electrical test probe marks 610, in accordance with an embodiment of the present invention. As can be seen, the size and shapes and locations of the electrical test probe marks are different from mark to mark, thus providing a unique fingerprint of the wafer upon which the electrical test probe marks are placed.

A further description will now be given regarding block 324C of method 300 of FIG. 3, in accordance with an embodiment of the present invention.

A wafer bevel edge structure can be used as wafer identifying indicia in order verify the authenticity of a wafer. SEM images include wafer bevel edge structure. The wafer bevel edge structure can be random and vary from wafer to wafer. It thus can be difficult if not impossible to clone a wafer with the wafer bevel edge structure of another wafer. Hence, the wafer bevel edge structure can be used as a unique identification of a wafer. A fiducial marker is used in combination with the images to provide reference location and reproducibility. In an embodiment, the images taken from multiple chips of a wafer can be combined to further enhance the uniqueness of wafer identification.

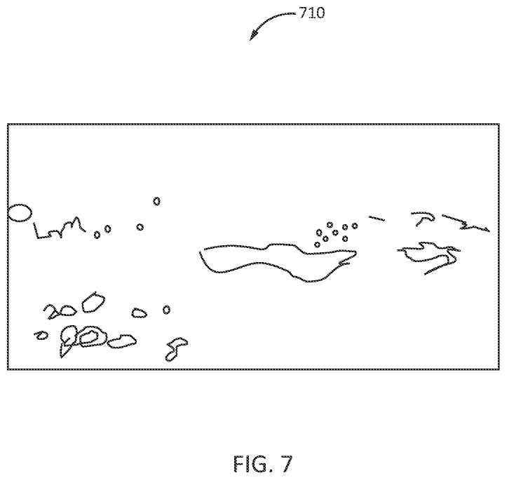

FIG. 7 is a block diagram showing a top-down schematic of a wafer bevel edge structure 710, in accordance with an embodiment of the present invention. As can be seen, imperfections in the edge structure are different from one edge portion to another edge portion, thus providing a unique fingerprint of the wafer having such edge structure.

A further description will now be given regarding block 324C of method 300 of FIG. 3, in accordance with an embodiment of the present invention.

A grain crystallographic morphology/structure can be used as wafer identifying indicia in order verify the authenticity of a wafer. SEM images include grain crystallographic morphology/structure. The grain crystallographic morphology/structure can be random and vary from chip to chip and from wafer to wafer. It thus can be difficult if not impossible to clone a wafer with the grain crystallographic morphology/structure of another wafer. Hence, the grain crystallographic morphology/structure can be used as a unique identification of a wafer. A fiducial marker is used in combination with the images to provide reference location and reproducibility. In an embodiment, the images taken from multiple chips of a wafer can be combined to further enhance the uniqueness of wafer identification.

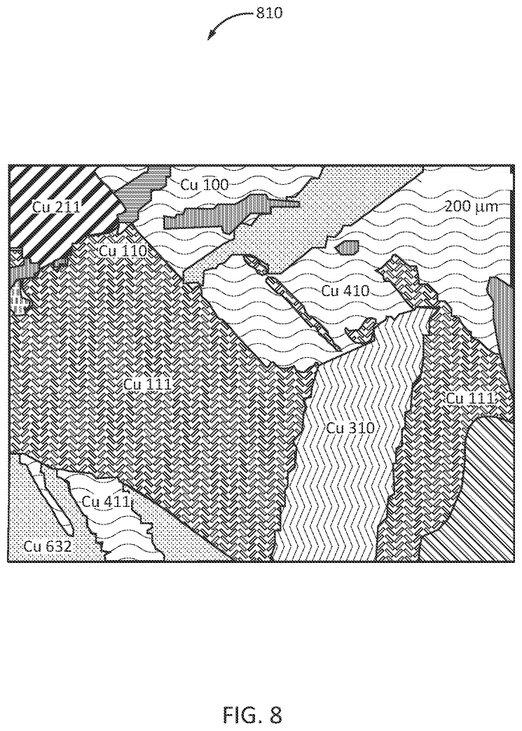

FIG. 8 is a block diagram showing a top-down schematic of a grain crystallographic morphology/structure 810, in accordance with an embodiment of the present invention. As can be seen, the sizes and shapes and locations of the grains are different from grain to grain, thus providing a unique fingerprint of the wafer having such structure.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method of wafer verification for split manufacturing, comprising:
capturing images of one or more different wafer features during manufacturing using a fiducial marker; and
comparing the images from one stage to a next stage for at least two stages of manufacturing to verify a wafer identification based on a matching of the one of more different wafer features from the one stage to the next stage.

2. The method of claim 1, wherein the one or more different wafer features comprise a grain distribution.

3. The method of claim 2, wherein the grain distribution comprises a grain distribution parameter selected from the group consisting of grain shapes and grain sizes

4. The method of claim 1, wherein the one or more different wafer features comprise an electrical test probe mark distribution.

5. The method of claim 1, wherein the one or more different wafer features comprise wafer bevel edge characteristics.

6. The method of claim 1, wherein the one or more different wafer features comprise a grain crystallographic structure.

7. The method of claim 1, wherein the fiducial mark is placed on the images for reference location and reproducibility.

8. The method of claim 1, wherein said capturing step captures multiple images involving multiple chips in order to enhance a uniqueness of a wafer identification.

9. The method of claim 1, wherein the method is performed across multiple foundries, with each of the multiple foundries performing said comparing step.

10. The method of claim 1, wherein each of the multiple foundries creates its own unique fingerprint based on the one or more different wafer features, and wherein a subsequent processing of the wafer by a subsequent foundry removes a prior fingerprint and creates a new unique fingerprint for use in an evaluation by a next foundry.

11. A wafer verification system for split manufacturing, comprising:
a wafer imaging system, disposed at each of a plurality of foundries performing the split manufacturing of a wafer, for capturing images of one or more different wafer features during manufacturing using a fiducial marker; and
a hardware processor, disposed at each of the plurality of foundries except a first foundry, for comparing the images from one stage to a next stage for at least two stages of manufacturing to verify a wafer identification based on a matching of the one of more different wafer features from the one stage to the next stage.

12. The wafer verification system of claim 11, wherein the one or more different wafer features comprise a grain distribution.

13. The wafer verification system of claim 12, wherein the grain distribution comprises a grain distribution parameter selected from the group consisting of grain shapes and grain sizes

14. The wafer verification system of claim 11, wherein the one or more different wafer features comprise an electrical test probe mark distribution.

15. The wafer verification system of claim 11, wherein the one or more different wafer features comprise wafer bevel edge characteristics.

16. The wafer verification system of claim 11, wherein the one or more different wafer features comprise a grain crystallographic structure.

17. The wafer verification system of claim 11, wherein the wafer imaging system at different ones of the plurality of foundries captures multiple images involving multiple chips in order to enhance a uniqueness of a wafer identification.

18. The wafer verification system of claim 11, wherein each of the plurality of foundries creates its own unique fingerprint based on the one or more different wafer features.

19. The wafer verification system of claim 18, wherein a subsequent processing of the wafer by a subsequent foundry removes a prior fingerprint and creates a new unique fingerprint for use in an evaluation by a next foundry.

20. A wafer verification system for split manufacturing, comprising:
a wafer imaging system, disposed at each of a plurality of foundries performing the split manufacturing of a wafer, for capturing images of one or more different wafer features during manufacturing using a fiducial marker; and
a hardware processor, disposed at each of the plurality of foundries except a first foundry, for comparing the images from one stage to a next stage for at least two stages of manufacturing to verify a wafer identification based on a matching of the one of more different wafer features from the one stage to the next stage,
wherein the one or more different wafer features are selected from the group consisting of a grain distribution, an electrical test probe mark distribution, wafer bevel edge characteristics, and a grain crystallographic structure.
